(19) United States
(12) Patent Application Publication
(10) Pub. No.: US 2016/0126347 A1
(43) Pub. Date: May 5, 2016

(54) SILICON CARBIDE SEMICONDUCTOR DEVICE

(71) Applicant: SUMITOMO ELECTRIC INDUSTRIES, LTD., Osaka-shi (JP)

(72) Inventors: Keiji WADA, Osaka-shi (JP); Takeyoshi MASUDA, Osaka-shi (JP)

(21) Appl. No.: 14/895,900

(22) PCT Filed: May 8, 2014
(86) PCT No.: PCT/JP2014/062305

§ 371 Date: Dec. 3, 2015

(30) Foreign Application Priority Data
Jun. 12, 2013 (JP) 2013-123782

(51) Int. Cl. H01L 29/78; H01L 29/04; H01L 29/10; H01L 29/16

(52) U.S. Cl. CPC H01L 29/7813; H01L 29/1608; H01L 29/045; H01L 29/1095

(57) ABSTRACT

A trench reaches a first layer of a first conductivity type from a second main surface through a third layer of the first conductivity type and a second layer of a second conductivity type. A contact region extends from the second main surface through the third layer and the second layer to a position deeper than an interface between the first layer and the second layer, and comes in contact with an embedded region. The contact region is higher in impurity concentration than the second layer. The embedded region has a first portion lying between the contact region and a first main surface in a direction of thickness and a second portion extending from the first portion toward the trench.

### TECHNICAL FIELD

This invention relates to a silicon carbide semiconductor device and particularly to a silicon carbide semiconductor device having a gate insulating film on a trench.

### BACKGROUND ART

According to Japanese Patent No. 3462506 (PTD 1), when an oxide breaks down due to concentration of electric field at a corner portion of a gate trench before breakdown of a bulk semiconductor in a silicon carbide metal oxide semiconductor field effect transistor (MOSFET), a breakdown voltage of the MOSFET may degrade. In order to suppress such concentration of electric field, formation of a p-type region under a source contact in an n-type epitaxial layer in an FET having a trench extending through a p-type epitaxial layer downward into the n-type epitaxial layer has been shown by way of example. This p-type region has a concentration of carriers higher than a concentration of carriers present in the p-type epitaxial layer and is formed adjacently to a gate trench.

### CITATION LIST

### Patent Document

PTD 1: Japanese Patent No 3462506

### SUMMARY OF INVENTION

### Technical Problem

According to the technique above, the source contact and the p-type region are electrically connected to each other with the p-type epitaxial layer being interposed. The carrier concentration in the p-type epitaxial layer, however is low. Therefore, stabilization of a potential of the p-type region owing to electrical connection with the source contact tends to be insufficient. Therefore, an effect of suppression of concentration of electric field by the p-type region is not sufficient, and consequently a desired breakdown voltage cannot be obtained in some cases.

The present invention was made to solve the problems as described above, and an object of this invention is to provide a silicon carbide semiconductor device having a high breakdown voltage.

### Solution to Problem

A silicon carbide semiconductor device according to the present invention has a silicon carbide layer a gate insulating film, a gate electrode, a first electrode, and a second electrode.

The silicon carbide layer has a direction of thickness. The silicon carbide layer has a first main surface and a second main surface opposed to the first main surface in the direction of thickness. The silicon carbide layer has a first layer, a second layer, a third layer, a contact region, and an embedded region. The first layer forms the first main surface. The first layer has a first conductivity type. The second layer is provided on the first layer as being spaced apart from the first main surface by the first layer. The second layer has a second conductivity type. The third layer is provided on the second layer as being spaced apart from the first layer by the second layer and forms the second main surface. The third layer has the first conductivity type. The silicon carbide layer is provided with a trench having a sidewall surface reaching the first layer from the second main surface through the third layer and the second layer. The contact region extends from the second main surface through the third layer and the second layer to a position deeper than an interface between the first and second layers and is distant from the first main surface. The contact region has the second conductivity type and is higher in impurity concentration than the second layer. The embedded region is distant from each of the first main surface, the second main surface, the second layer, the third layer, and the trench and in contact with the contact region. The embedded region has the second conductivity type. The embedded region has a first portion lying between the contact region and the first main surface in the direction of thickness and a second portion extending from the first portion toward the trench.

The gate insulating film is provided on the trench. The gale electrode is provided on the gate insulating film. The first electrode is provided on the first main surface of the silicon carbide layer. The second electrode is provided on the second main surface of the silicon carbide layer and in contact with each of the third layer and the contact region.

### Advantageous Effects of Invention

According to this silicon carbide semiconductor device, the contact region connecting the embedded region as an electric field relaxation structure and the second electrode to each other is higher in impurity concentration than the second layer. Thus, the embedded region is connected to the second electrode with low resistance. Therefore, a potential of the electric field relaxation structure is sufficiently stabilized. Therefore, concentration of electric field which can be a cause of breakdown of the silicon carbide semiconductor device is further suppressed. Consequently, a breakdown voltage of the silicon carbide semiconductor device can be higher.

### BRIEF DESCRIPTION OF DRAWINGS

FIG. 1 is a partial cross-sectional view schematically showing a construction of a silicon carbide semiconductor device in one embodiment of the present invention, along the line I-I in FIGS 2 and 3.

FIG 2 is a partial perspective view schematically showing a shape of a silicon carbide layer in the silicon carbide semiconductor device in FIG. 1.

FIG. 3 is a partial plan view schematically showing a shape of the silicon carbide layer in the silicon carbide semiconductor device in FIG. 1.

FIG. 4 is a partial cross-sectional view schematically showing a first step in a method for manufacturing the silicon carbide semiconductor device in FIG. 1.

FIG. 5 is a partial cross-sectional view schematically showing a second step in the method for manufacturing the silicon carbide semiconductor device in FIG. 1.

FIG. 6 is a partial cross-sectional view schematically showing a third step in the method for manufacturing the silicon carbide semiconductor device in FIG. 1.

FIG. 7 is a partial cross-sectional view schematically showing a fourth step in the method for manufacturing the silicon carbide semiconductor device in FIG. 1.

FIG. 8 is a partial cross-sectional view schematically showing a fifth step in the method for manufacturing the silicon carbide semiconductor device in FIG. 1.

FIG. 9 is a partial cross-sectional view schematically showing a sixth step in the method for manufacturing the silicon carbide semiconductor device in FIG. 1.

FIG. 10 is a partial cross-sectional view schematically showing a seventh step in the method for manufacturing the silicon carbide semiconductor device in FIG. 1.

FIG. 11 is a partial cross-sectional view schematically showing an eighth step in the method for manufacturing the silicon carbide semiconductor device in FIG. 1.

FIG. 12 is a partial cross-sectional view schematically showing a ninth step in the method for manufacturing the silicon carbide semiconductor device in FIG. 1.

FIG. 13 is a partial cross-sectional view schematically showing a tenth step in the method for manufacturing the silicon carbide semiconductor device in FIG. 1.

FIG. 14 is a partial cross-sectional view schematically showing an eleventh step in the method for manufacturing the silicon carbide semiconductor device in FIG. 1.

FIG. 15 is a graph showing one example of relation between a coordinate along an arrow X in FIG. 1 and electric field intensity.

FIG. 16 is a partial cross-sectional view schematically showing a microstructure at a surface of a silicon carbide layer in a silicon carbide semiconductor device.

FIG. 17 is a diagram showing crystal structure at a (000-1) plane in a hexagonal crystal having a poly type of 4H.

FIG. 18 is a diagram showing crystal structure at a (11-20) plane along the line XVIII-XVIII in FIG. 17.

FIG. 19 is a diagram showing in a (11-20) plane, crystal structure in the vicinity of a surface of a combined surface in FIG. 16.

FIG. 20 is a diagram when the combined surface in FIG. 16 is viewed from a (01-10) plane.

FIG. 21 is a graph showing one example of relation of a macroscopically viewed angle between a channel surface and a (000-1) plane with channel mobility, in each of a case where thermal etching is performed and a case where it is not performed.

FIG. 22 is a graph showing one example of relation of an angle between a channel direction and a <0-11-2> direction with channel mobility.

FIG. 23 is a diagram showing a variation of FIG. 16.

### DESCRIPTION OF EMBODIMENTS

An embodiment of the present invention will be described hereinafter with reference to the drawings. It is noted that, in the drawings below, the same or corresponding elements have the same reference characters allotted and description thereof will not be repeated. In addition, regarding crystallographic denotation herein, an individual orientation, a group orientation, an individual plane, and a group plane are shown in [|, <>, ( ), and {}, respectively. Moreover, a crystallographically negative index is normally expressed by a number with a bar “−” thereabove, however, a negative sign herein precedes a number.

(Overview)

Overview of the embodiment will initially be described in (i) to (ix) below.

(i) A silicon carbide semiconductor device 200 has a silicon carbide layer 100, a gate insulating film 91, agate electrode 92, a first electrode 98, and a second electrode 94.

Silicon carbide layer 100 has a direction of thickness. Silicon carbide layer 100 has a first main surface P1 and a second main surface P2 opposed to first main surface P1 in the direction of thickness. Silicon carbide layer 100 includes a first layer 81, a second layer 82, a third layer 83, a contact region 84, and an embedded region 85. First layer 81 forms first main surface P1. First layer 81 has a first conductivity type. Second layer 82 is provided on first layer 81 as being spaced apart from first main surface P1 by first layer 81. Second layer 82 has a second conductivity type. Third layer 83 is provided on second layer 82 as being spaced apart from first layer 81 by second layer 82 and forms second main surface P2. Third layer 83 has the first conductivity type. Silicon carbide layer 100 is provided with a trench TR having a sidewall surface SW reaching first layer 81 from second main surface P2 through third layer 83 and second layer 82. Contact region 84 extends from second main surface P2 through third layer 83 and second layer 82 to a position deeper than an interface between first layer 81 and second layer 82 and is distant from first main surface P1. Contact region 84 has the second conductivity type and is higher in impurity concentration than second layer 82. Embedded region 85 is distant from each of first main surface P1, second main surface P2, second layer 82, third layer 83, and trench TR and in contact with contact region 84. Embedded region 85 has the second conductivity type. Embedded region 85 has a first portion 85a lying between contact region 84 and first main surface P1 in the direction of thickness and a second portion 85b extending from first portion 85a toward trench TR.

Gate insulating film 91 is provided on trench TR. Gate electrode 92 is provided on gate insulating film 91. First electrode 98 is provided on first main surface P1 of silicon carbide layer 100. Second electrode 94 is provided on second main surface P2 of silicon carbide layer 100 and in contact with each of third layer 83 and contact region 84.

According to this silicon carbide semiconductor device 200, contact region 84 connecting embedded region 85 as the electric field relaxation structure and second electrode 94 to each other is higher in impurity concentration than second layer 82. Thus, embedded region 85 is connected to second electrode 94 with low resistance. Therefore, a potential of the electric field relaxation structure is sufficiently stabilized. Therefore, concentration of electric field which can be a cause of breakdown of silicon carbide semiconductor device 200 can further be suppressed. Consequently, a breakdown voltage of silicon carbide semiconductor device 200 can be higher.

(ii) In (i), first layer 81 may include a first region 81a which forms first main surface P1 and a second region 81b which is provided between first region 81a and second layer 82 and is higher in impurity concentration than first region 81a. Sidewall surface SW of trench TR reaches first region 81a through second region 81b. Second region 81b is located between second portion 85b of embedded region 85 and second layer 82 in the direction of thickness.

Thus, while an ON resistance is suppressed owing to a high impurity concentration in second region 81b, a breakdown voltage can be higher owing to a low impurity concentration in first region 81a.

(iii) In (i) or (ii), at least a part of embedded region 85 may be higher in impurity concentration than second layer 82.

Thus, a voltage at which embedded region 85 is completely depleted becomes higher. Therefore, concentration of electric field is sufficiently suppressed also under a higher voltage.

(iv) The embedded region may be distant from the trench by not smaller than 1 μm and not greater than 4 μm.

With a distance between the embedded region and the trench being not smaller than 1 μm, an ON resistance can be prevented from becoming excessively high. With this distance being not greater than 4 μm, concentration of electric field in the trench can further be suppressed.

(v) The second portion of the embedded region may extend by not smaller than 1 μm from the first portion of the embedded region toward the trench.

Thus, a distance between the embedded region and the trench can be made smaller without the first portion of the embedded region being made larger. Therefore, while a size of the silicon carbide semiconductor device is suppressed, concentration of electric field can be suppressed.

(vi) In (i) to (v), on sidewall surface SW of trench TR, second layer 82 may be provided with a surface including a first surface S1 having a plane orientation {0-33-8}.

Thus, of ON resistance of silicon carbide semiconductor device 200, a resistance of a channel portion which is a portion formed by second layer 82 can be lowered. Therefore, a higher resistance of a drift layer portion which is a portion formed from first layer 81 is allowed. Therefore, an impurity concentration in first layer 81 can be lower. Thus, a breakdown voltage can be higher.

(vii) In (vi), the surface may microscopically include first surface S1 and the surface may microscopically further include a second surface S2 having a plane orientation {0-11-1}.

Thus, a resistance in the channel portion can further be lowered.

(viii) In (vii), first surface S1 and second surface S2 of the surface may form a combined surface SR having a plane orientation {0-11-2}.

Thus, a resistance in the channel portion can further be lowered.

(ix) In (viii), the surface may macroscopically have an off angle of 62°+10° with respect to a {000-1} plane.

Thus, a resistance in the channel portion can further be lowered.

(Details)

Details of the embodiment will now be described below.

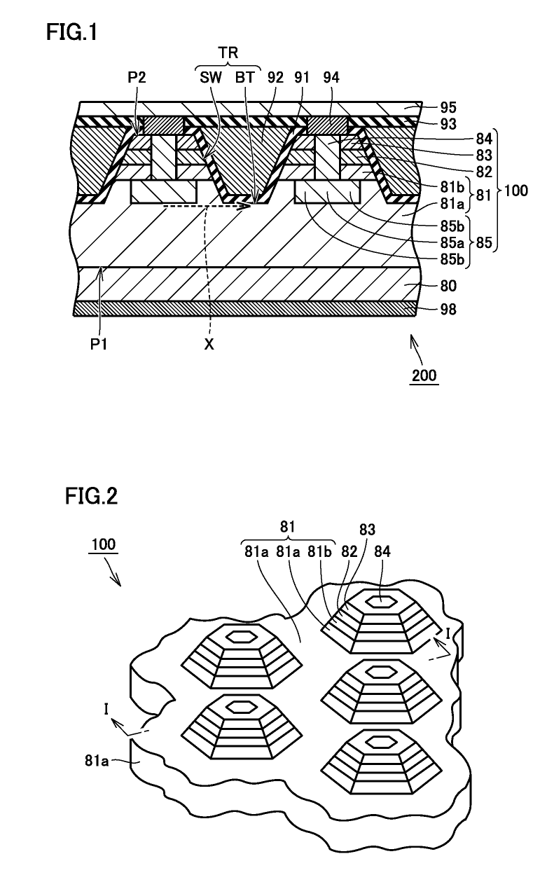

As shown in FIG. 1, a MOSFET 200 (a silicon carbide semiconductor device) in the present embodiment has a single crystal substrate 80, an epitaxial layer 100 (a silicon carbide layer), a gate oxide film 91 (a gate insulating film), gate electrode 92, an interlayer insulating film 93, a source electrode 94 (a second electrode), a source interconnection layer 95, and a drain electrode 98 (a first electrode). Single crystal substrate 80 is composed of silicon carbide and has an n-type (a first conductivity type). Epitaxial layer 100 is provided on single crystal substrate 80.

Epitaxial layer 100 is a silicon carbide layer epitaxially grown on single crystal substrate 80. Epitaxial layer 100 has hexagonal crystal structure having a poly type of 4H. Epitaxial layer 100 has a direction of thickness (a vertical direction in FIG. 1). Epitaxial layer 100 has a lower surface P1 (a first main surface) facing single crystal substrate 80 and an upper surface P2 (a second main surface opposite to the first main surface) opposed to lower surface P1 in the direction of thickness. Epitaxial layer 100 has an n drift layer 81 (a first layer), a p base layer 82 (a second layer), an n layer 83 (a third layer), contact region 84, and embedded region 85.

N drift layer 81 forms lower surface P1 of epitaxial layer 100. N drift layer 81 has the n-type. An impurity concentration in n drift layer 81 is preferably lower than an impurity concentration in single crystal substrate 80. An impurity concentration in n drift layer 81 is preferably not lower than 1×10¹⁵ cm³ and not higher than 5×10¹⁶ cm⁴.

P base layer 82 has a p-type (a second conductivity type different from the first conductivity type). P base layer 82 is provided on n drift layer 81 as being spaced apart from lower surface P1 by n drift layer 81. An impurity concentration in p base layer 82 is preferably not lower than 5×10¹⁵ cm⁻³ and not higher than 2×10¹⁸ cm⁻³ and it is set, for example, to 1×10¹⁸ cm³.

N layer 83 has the n-type. N layer 83 is provided on p base layer 82 to be spaced apart from n drift layer 81 by p base layer 82. N layer 83 forms upper surface P2 of epitaxial layer 100, together with contact region 84.

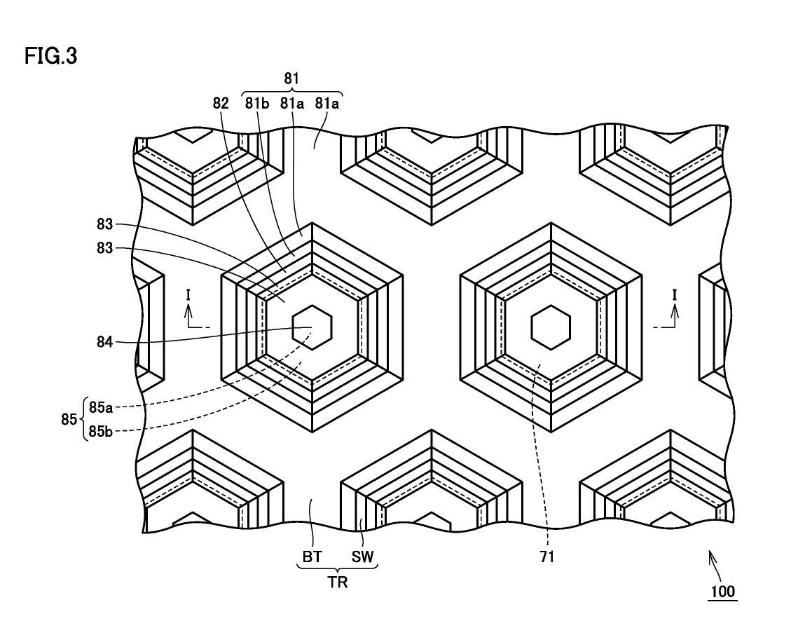

Referring further to FIGS. 2 and 3, trench TR is provided in epitaxial layer 100. Trench TR has sidewall surface SW and a bottom surface BT. A depth of trench TR is, for example, approximately from 0.8 to 1.8 μm.

Sidewall surface SW reaches n drift layer 81 from upper surface P2 through n layer 83 and p base layer 82. Sidewall surface SW includes a channel surface of MOSFET 200 on p base layer 82. Preferably, sidewall surface SW is inclined with respect to upper surface P2 of epitaxial layer 100, and in this case, trench TR is tapered toward bottom surface BT. A plane orientation of sidewall surface SW is inclined preferably by not smaller than 50° and not greater than 65° with respect to a {0001} plane and more preferably inclined by not smaller than 50° and not greater than 65° with respect to a (000-1) plane. Preferably, sidewall surface SW has a prescribed crystal plane (also referred to as a special surface) in particular in a portion on p base layer 82. Details of the special surface will be described later.

Bottom surface BT is located on n drift layer 81 and preferably on a lower region 81a which will be described later. In the present embodiment, bottom surface BT has a fiat shape substantially in parallel to upper surface P2. A portion where bottom surface BT and sidewall surface SW are connected to each other forms a corner portion of trench TR. In the present embodiment, trench TR extends to form a mesh having a honeycomb structure in a plan view (FIG. 3). Thus, epitaxial layer 100 has upper surface P2 surrounded by trenches TR and having a hexagonal shape.

Contact region 84 has the p-type and is higher in impurity concentration than p base layer 82. An impurity concentration in contact region 84 is preferably not lower than 1×10¹⁸ cm³ and not higher than 1×10²⁰ cm³. Contact region 84 is connected to p base layer 82. Contact region 84 extends from upper surface P2 through n layer 83 and p base layer 82 to a position deeper than an interface between n drift layer 81 and p base layer 82 and is distant from lower surface P1.

Embedded region 85 has the p-type. An impurity in embedded region 85 is represented, for example, by aluminum. At least a part of embedded region 85 is preferably higher in impurity concentration than p base layer 82. In other words, a maximum value of an impurity concentration profile in the direction of thickness (the vertical direction in FIG. 1) in embedded region 85 is greater than a maximum value of an impurity concentration profile in p base layer 82. The maximum value of an impurity concentration in embedded region 85 is preferably not lower than 1×10¹⁷ cm⁻³ and not higher than 1×10¹⁹ cm³. A value obtained by integrating impurity concentrations per unit volume of embedded region 85 in a direction of thickness (the vertical direction in FIG. 1) corresponds to a dose amount in ion implantation for forming embedded region 85. This dose amount is preferably not less than 1×10¹² cm⁻² and not more than 1×10¹⁵ cm⁻² and it is set, for example, to 1×10¹³ cm⁻².

Embedded region 85 is distant from each of lower surface P1, upper surface P2, p base layer 82, n layer 83, and trench TR. Embedded region 85 is in contact with contact region 84.

As shown in FIG. 1, embedded region 85 has a connection portion 85a (a first portion) lying between contact region 84 and lower surface P1 in the direction of thickness and an extension portion 85b (a second portion) extending from connection portion 85a toward a corner portion of trench TR. In other words, embedded region 85 has connection portion 85a superimposed on contact region 84 in a plan view (FIG. 3) and extension portion 85b extending from connection portion 85a toward trench TR. Extension portion 85b of embedded region 85 preferably extends by not smaller than 1 μm and not greater than 3 μm from connection portion 85a of embedded region 85 toward trench TR.

A distance between embedded region 85 and trench TR is preferably not smaller than 1 82 m and more preferably not smaller than 2 μm. This distance is preferably not greater than 4 μm and more preferably not greater than 3 μm.

N drift layer 81 preferably includes lower region 81a (the first region) forming lower surface P1 and an upper region 81b (a second region) provided between lower region 81a and p base layer 82 and being higher in impurity concentration than lower region 81a. Sidewall surface SW of trench TR reaches lower region 81a through upper region 81b. Upper region 81b is located between extension portion 85b of embedded region 85 and p base layer 82 in the direction of thickness.

Gate oxide film 91 is provided on trench TR and covers each of sidewall surface SW and bottom surface BT of trench TR. Gate electrode 92 is provided on gate oxide film 91. Gate oxide film 91 is preferably a silicon oxide film.

Source electrode 94 is provided on upper surface P2 of epitaxial layer 100 and in contact with each of n layer 83 and contact region 84. Source interconnection layer 95 is in contact with source electrode 94. Source interconnection layer 95 is, for example, an aluminum layer. Interlayer insulating film 93 isolates gate electrode 92 and source interconnection layer 95 from each other. Drain electrode 98 is provided on lower surface P1 of epitaxial layer 100 with single crystal substrate 80 being interposed.

A method of manufacturing MOSFET 200 (FIG. 1) will now be described below.

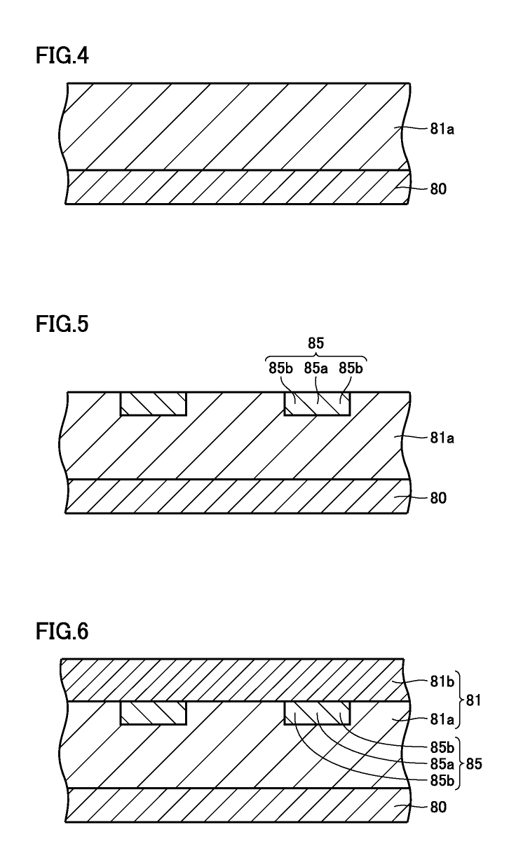

As shown in FIG. 4, lower region 81a forming a part of drift layer 81 (FIG. 1) is formed on single crystal substrate 80. Specifically, lower region 81a is formed through epitaxial growth on single crystal substrate 80. This epitaxial growth can be achieved with CVD (Chemical Vapor Deposition) in which, for example, a gas mixture of silane (SiH₄) and propane (C₃H₈) is used as a source gas, and, for example, a hydrogen gas (H₂) is used as a carrier gas. Here, for example, nitrogen (N) or phosphorus (P) is preferably introduced as an impurity.

As shown in FIG. 5, embedded region 85 is formed in a part of lower region 81a. Specifically, ions are implanted into lower region 81a with the use of an implantation mask (not shown).

As shown in FIG. 6, upper region 81b is formed on lower region 81a where embedded region 85 is provided. Thus, embedded region 85 is embedded in n drift layer 81 formed from lower region 81a and upper region 81b. Upper region 81b can be formed with a method the same as the method of forming lower region 81a.

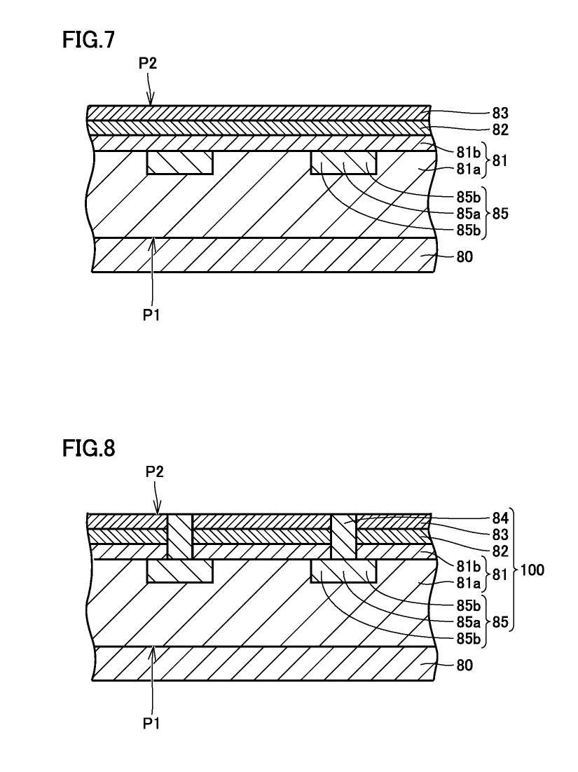

As shown in FIGS. 7 and 8, p base layer 82, n layer 83, and contact region 84 are formed. Formation thereof can be achieved, for example, by ion implantation into n drift layer 81 (FIG. 6). In ion implantation for forming p base layer 82 and contact region 84, ions of an impurity for providing the p-type such as aluminum (Al) are implanted. Alternatively, in ion implantation for forming n layer 83, ions of an impurity for providing the n-type such as phosphorus (P) are implanted. For example, p base layer 82 is formed through ion implantation to a depth approximately from 0.7 to 0.8 μm. N layer 83 is formed through ion implantation such that a channel length of MOSFET 200 is substantially approximately from 0.3 to 0.6 μm.

Epitaxial growth accompanying addition of an impurity may be employed instead of ion implantation.

Then, heat treatment for activating an impurity is performed. A temperature for this heat treatment is preferably not lower than 1500° C. and not higher than 1900° C. and it is set, for example, to approximately 1700° C. A time period for heat treatment is set, for example, to approximately 30 minutes. An atmosphere for heat treatment is preferably an inert gas atmosphere, and for example, an Ar atmosphere is adopted.

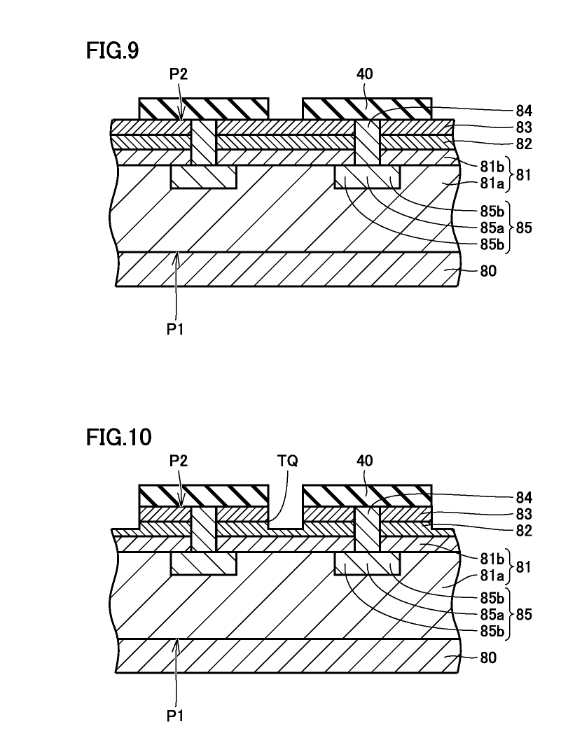

As shown in FIG. 9, a mask layer 40 having an opening is formed on upper surface P2 formed by n layer 83 and contact region 84. The opening is formed in correspondence with a position of trench TR (FIG. 1). A silicon oxide film is preferably employed as mask layer 40. The silicon oxide film can be formed by thermally oxidizing upper surface P2.

As shown in FIG. 10, in the opening in mask layer 40, a part of the epitaxial layer on single crystal substrate 80 is etched away. As an etching method, for example, reactive ion etching (RIE) or inductively coupled plasma (ICP) RIE can be employed. Specifically, ICP-RIE using, for example, SF₆ or a gas mixture of SF₆ and O₂ as a reaction gas can be employed. Through such etching, a recess TQ having a sidewall substantially perpendicular to upper surface P2 is formed in a region where trench TR (FIG. 1) should be formed.

Then, thermal etching is performed in recess TQ. Thermal etching can be performed, for example, through heating in an atmosphere containing a reactive gas having at least one or more types of halogen atoms. At least one or more types of halogen atoms include at least any of chlorine (Cl) atoms and fluorine (F) atoms. This atmosphere is, for example, of Cl₂, BCl₃, ST₆, or CF₄. Thermal etching is performed in such a manner that, for example, a gas mixture of a chlorine gas and an oxygen gas is used as a reaction gas and a temperature for heat treatment, for example, not lower than 700° C. and not higher than 1000° C. is set.

It is noted that the reaction gas may contain a carrier gas in addition to the chlorine gas and the oxygen gas described above. For example, a nitrogen (N₂) gas, an argon gas, a helium gas, or the like can be employed as a carrier gas. Then, in a case where a temperature for heat treatment not lower than 700° C. and not higher than 1000° C. is set as described above, a rate of etching SiC attains, for example, to approximately 70 μm/hour. In addition, in this case, since mask layer 40 made of silicon oxide is extremely high in rate of selective etching of SiC, it is not substantially etched during etching of SiC.

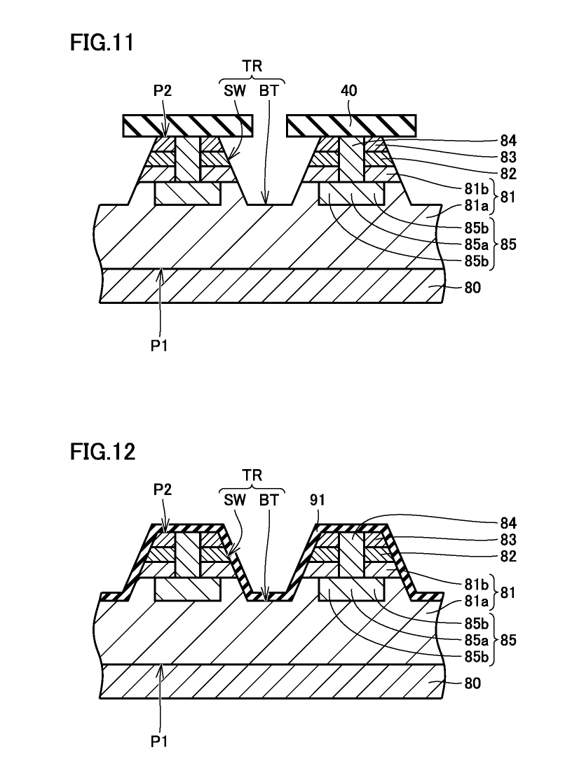

As shown in FIG. 11, through thermal etching above, trench TR is formed in upper surface P2 of epitaxial layer 100. Preferably, at the time of formation of trench TR, self-format ion of a special surface on sidewall surface SW, in particular on p base layer 82, takes place. Then, mask layer 40 is removed with any method such as etching.

As shown in FIG. 12, gate oxide film 91 covering each of sidewall surface SW and bottom surface BT of trench TR is formed. Gate oxide film 91 can be formed, for example, through thermal oxidation.

After gate oxide film 91 is formed, NO annealing using a nitrogen monoxide (NO) gas as an atmospheric gas may be performed. A temperature profile has a condition, for example, of a temperature not lower than 1100° C. and not higher than 1300° C. and a retention time period around 1 hour. Thus, nitrogen atoms are introduced in an interface region between gate oxide film 91 and p base layer 82. Consequently, formation of interface state at the interface region is suppressed, so that channel mobility can be improved. It is noted that, if such nitrogen atoms can be introduced, a gas other than the NO gas may be employed as an atmospheric gas.

After this NO annealing, Ar annealing using argon (Ar) as an atmospheric gas may further be performed. A heating temperature in Ar annealing is preferably higher than a heating temperature in NO annealing above and lower than a melting point of gate oxide film 91. A time period during which this heating temperature is retained is set, for example, to approximately 1 hour. Thus, formation of interface state at the interface region between gate oxide film 91 and p base layer 82 is further suppressed. It is noted that other inert gases such as a nitrogen gas may be employed as an atmospheric gas instead of the Ar gas.

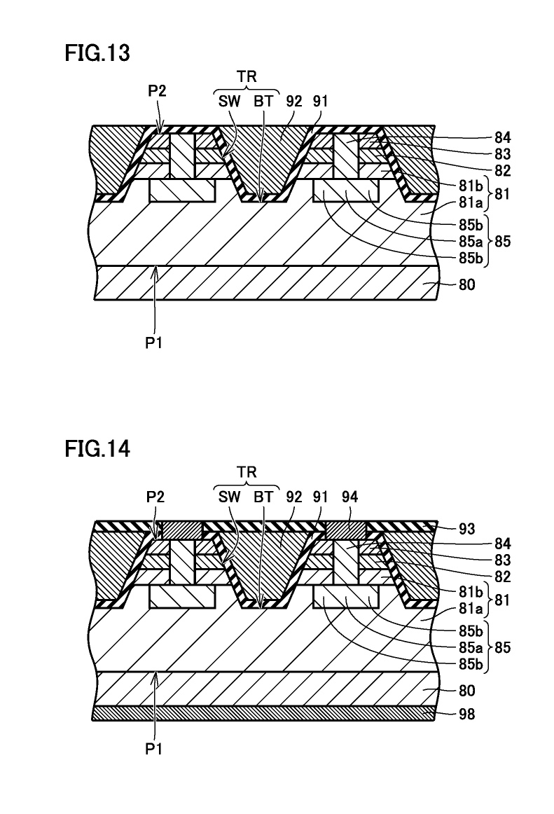

As shown in FIG. 13, gate electrode 92 is formed on gate oxide film 91. Specifically, gate electrode 92 is formed on gate oxide film 91 so as to bury a region inside trench TR with gate oxide film 91 being interposed. A method of forming gate electrode 92 can be performed, for example, by forming a film of a conductor or doped polysilicon and performing CMP (Chemical Mechanical Polishing) or RIE.

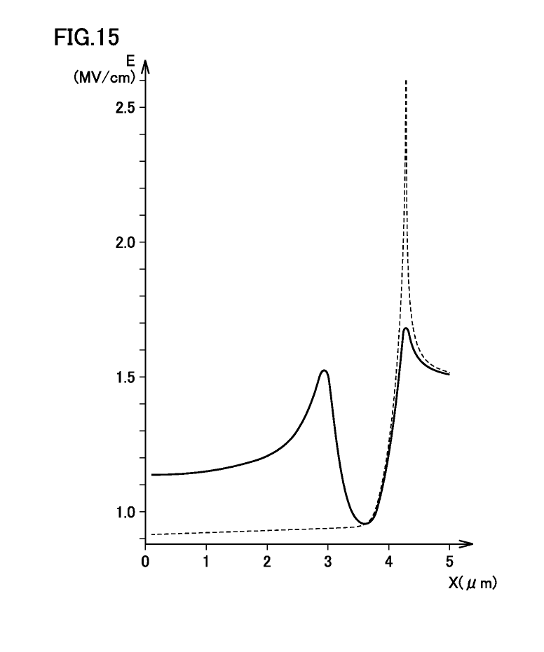

Referring to FIG. 14, interlayer insulating film 93 is formed on gate electrode 92 and gate oxide film 91 so as to cover an exposed surface of gate electrode 92. Etching is performed to form an opening in interlayer insulating film 93 and gate oxide film 91. This opening exposes each of n layer 83 and p contact region 84 at upper surface P2. Then, source electrode 94 in contact with each of n layer 83 and n contact region 84 is formed on upper surface P2. Drain electrode 98 is formed on lower surface P1 formed from n drift layer 81, with single crystal substrate 80 being interposed.

Referring again to FIG. 1, source interconnection layer 95 is formed. Thus, MOSFET 200 is obtained.

A result of simulation for verifying an effect of contact region 84 and embedded region 85 (FIG. 1) will be described below with reference to FIG. 15.

In a comparative example, that is, in a ease that contact region 84 and embedded region 85 are not provided, as shown with a dashed line in the figure, electric field intensity E, in the vicinity of X. 4.25 μm corresponding to the corner portion of trench TR in epitaxial layer 100 was 2.6 MV/cm. In this case, in consideration of a ratio of a dielectric constant between silicon carbide which is a material for epitaxial layer 100 and silicon oxide which is a material for gate oxide film 91, electric field of approximately 9 MV/cm is applied to gate oxide film 91. Consequently, it is predicted that breakdown of gate oxide film 91 may take place at a high probability.

In contrast, when contact region 84 and embedded region 85 (FIG. 1) are provided as in the present embodiment as shown with a solid line in the figure, electric field intensity E in the vicinity of X. 4.25 μm corresponding to the corner portion of trench TR in epitaxial layer 100 was suppressed to 1.7 MV/cm. In this ease, electric field applied to gate oxide film 91 is suppressed to approximately 5.5 MV/cm. Consequently, it is predicted that breakdown of gate oxide film 91 is prevented.

In this simulation, a voltage of drain electrode 98 applied to source interconnection layer 95 was set to 1200 V. A cell pitch (a period of the structure in FIG. 1) was set to 10 μm. Lower region 81a in n drift layer 81 had a thickness of 11 μm and an impurity concentration of 4×10¹⁵ cm³. Embedded region 85 had a width (a length in a lateral direction in FIG. 1) of 3 μm. Embedded region 85 was formed by adding aluminum at a dose amount of 3×10¹³ cm². Upper region 81b of n drift layer 81 had a thickness of 1 μm and an impurity concentration of 7.5×10¹⁵ cm³.

According to the present embodiment, contact region 84 connects embedded region 85 as the electric field relaxation structure and source electrode 94 to each other. Since contact region 84 is higher in impurity concentration than p base layer 82, embedded region 85 is connected to source electrode 94 with low resistance. Therefore, a potential of the electric field relaxation structure is sufficiently stabilized. Therefore, concentration of electric field which can be a cause of breakdown of MOSFET 200 is further suppressed. Consequently, a breakdown voltage of MOSFET 200 can be higher.

In n drift layer 81, while an ON resistance is suppressed owing to a high impurity concentration in upper region 81b, a breakdown voltage can be higher owing to a low impurity concentration in lower region 81a.

At least a part of embedded region 85 is preferably higher in impurity concentration than p base layer 82. Thus, a voltage at which embedded region 85 is completely depleted becomes higher. Therefore, concentration of electric field is sufficiently suppressed also under a higher voltage.

Embedded region 85 is preferably distant from trench TR by not smaller than 1 μm and not greater than 4 μm. With a distance between embedded region 85 and trench TR being not smaller than 1 μm, an ON resistance can be prevented from becoming excessively high. With this distance being not greater than 4 μm, concentration of electric field in the trench can further be suppressed.

Extension portion 85b of embedded region 85 preferably extends by not smaller than 1 μm from connection portion 85a of embedded region 85 toward trench TR. Thus, a distance between embedded region 85 and trench TR can be made smaller without connection portion 85a of embedded region 85 being made larger in the plan view (FIG. 3). Therefore, while a size of MOSFET 200 is suppressed, concentration of electric field can be suppressed.

(Special Surface)

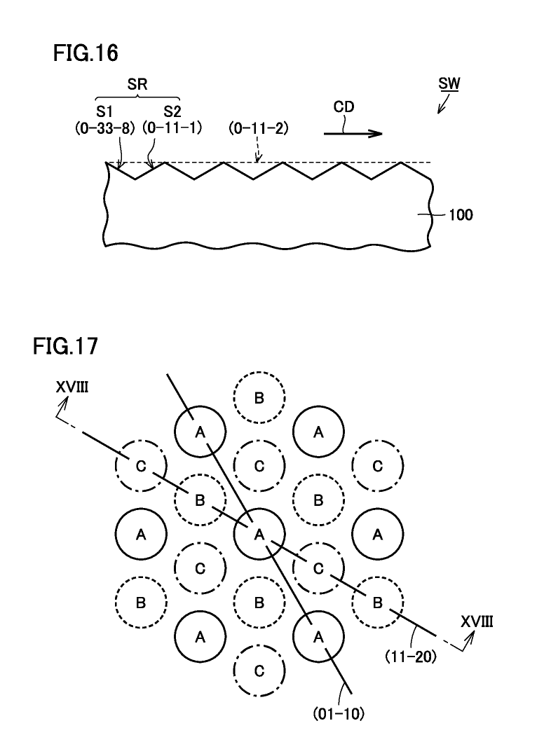

On sidewall surface SW (FIG. 1) of trench TR, p base layer 82 is preferably provided with a special surface as a surface. Sidewall surface SW having the special surface includes a surface S1 (a first surface) having a plane orientation {0-33-8} as shown in FIG. 16. In other words, on sidewall surface SW of trench TR, p base layer 82 is provided with a surface including surface S1. Surface S1 preferably has a plane orientation (0-33-8).

More preferably, sidewall surface SW microscopically includes surface S1, and sidewall surface SW microscopically further includes a surface S2 (a second surface) having a plane orientation {0-11-1}. Here, “microscopic” means in detail to such an extent that a dimension about twice as large as interatomic spacing is at least taken into consideration. As a method of observing such a microscopic structure, for example. TEM (Transmission Electron Microscope) can be employed Surface S2 preferably has a plane orientation (0-11-1).

Preferably, surface S1 and surface S2 of sidewall surface SW form combined surface SR having a plane orientation {0-11-2}. Namely, combined surface SR is formed by periodic repetition of surfaces S1 and S2. Such a periodic structure can be observed, for example, with TEM or AFM (Atomic force Microscopy). In this case, combined surface SR has an off angle of 62° macroscopically with respect to the {000-1} plane. Here, “macroscopic” means ignoring a microstructure having a dimension as small as interatomic spacing. For measuring such a macroscopic off angle, for example, a method with the use of general X-ray diffraction can be employed. Preferably, combined surface SR has a plane orientation (0-11-2). In this case, combined surface SR has an OFF angle of 62° macroscopically with respect to a (000-1) plane.

Preferably, a channel direction CD representing a direction in which carriers flow over a channel surface (that is, a direction of thickness of a MOSFFT (the vertical direction in FIG. 1 and the like)) extends along a direction in which periodic repetition described above appears.

A detailed structure of combined surface SR will now be described.

In general, when silicon carbide single crystal of a poly type of 4H is viewed from the (000-1) plane, as shown in FIG. 17, Si atoms (or C atoms) are provided such that atoms in an A layer (a solid line in the figure), atoms in a B layer located thereunder (a dashed line in the figure), atoms in a C layer located thereunder (a chain dotted line in the figure), and atoms in the B layer located thereunder (not shown) are repeatedly provided. Namely, such a periodic stack structure as ABCBABCBABCB . . . with four layers of ABCB being defined as one period is provided.

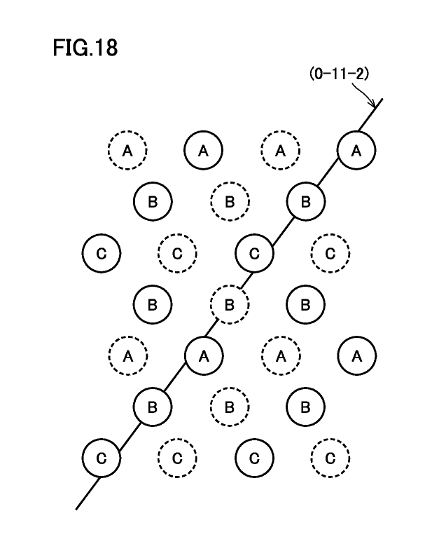

As shown in FIG. 18, at a (11-20) plane (a cross-section along the line XVIII-XVIII in FIG. 17), atoms in each layer of four layers of ABCB forming one period described above are not aligned to completely extend along a (0-11-2) plane. FIG. 18 shows the (0-11-2) plane as it passes through positions of atoms in the B layer, and in this case, it can be seen that atoms in each of the A layer and the C layer are displaced from the (0-11-2) plane. Therefore, even though a macroscopic plane orientation of a surface of silicon carbide single crystal, that is, a plane orientation in a case where an atomic-level structure is ignored, is limited to (0-11-2), this surface can microscopically take various structures.

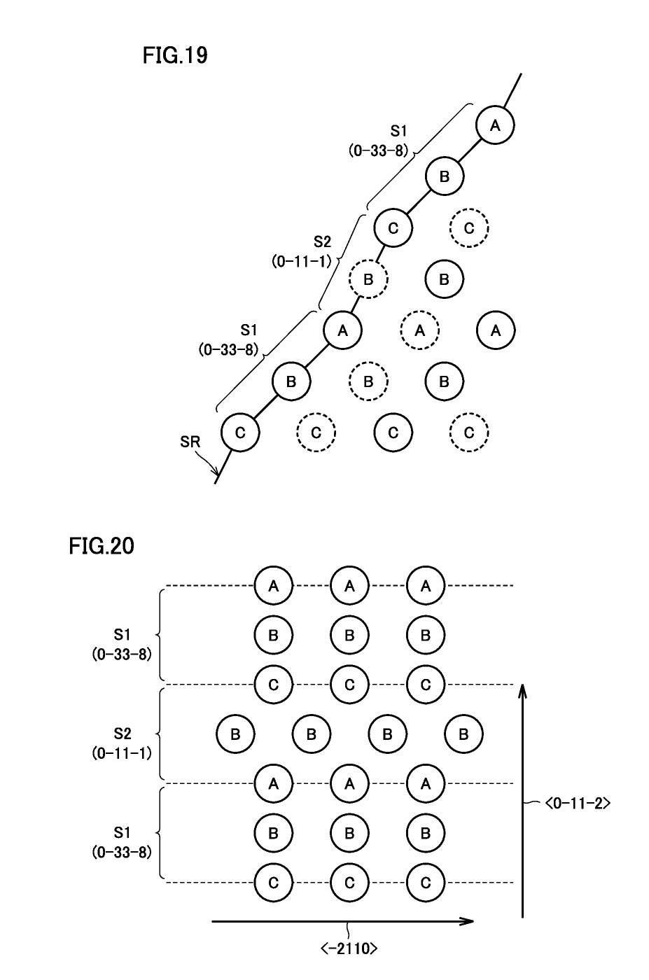

As shown in FIG. 19, combined surface SR is formed in such a manner that surface S1 having the plane orientation (0-33-8) and surface S2 connected to surface S1 and having a plane orientation different from the plane orientation of surface S1 are alternately provided. A length of each of surface S1 and surface S2 is twice as large as interatomic spacing of Si atoms (or C atoms). It is noted that a surface obtained by averaging surface S1 and surface S2 corresponds to the (0-11-2) plane.

As shown in FIG. 20, when combined surface SR is viewed from a (01-10) plane, single crystal structure periodically includes a structure equivalent to cubic crystal in part (a portion of surface S1). Specifically, combined surface SR is formed in such a manner that surface S1 having a plane orientation (001) in structure equivalent to the cubic crystal described above and surface S2 connected to surface S1 and having a plane orientation different from the plane orientation of surface S1 are alternately provided. Thus, it is also possible in a poly type other than 4H to form a surface from a surface having the plane orientation (001) in the structure equivalent to the cubic crystal (surface S1 in FIG. 17) and a surface connected to this surface and having a plane orientation different from this plane orientation (surface S2 in FIG. 17). The poly type may be, for example, 6H or 15R.

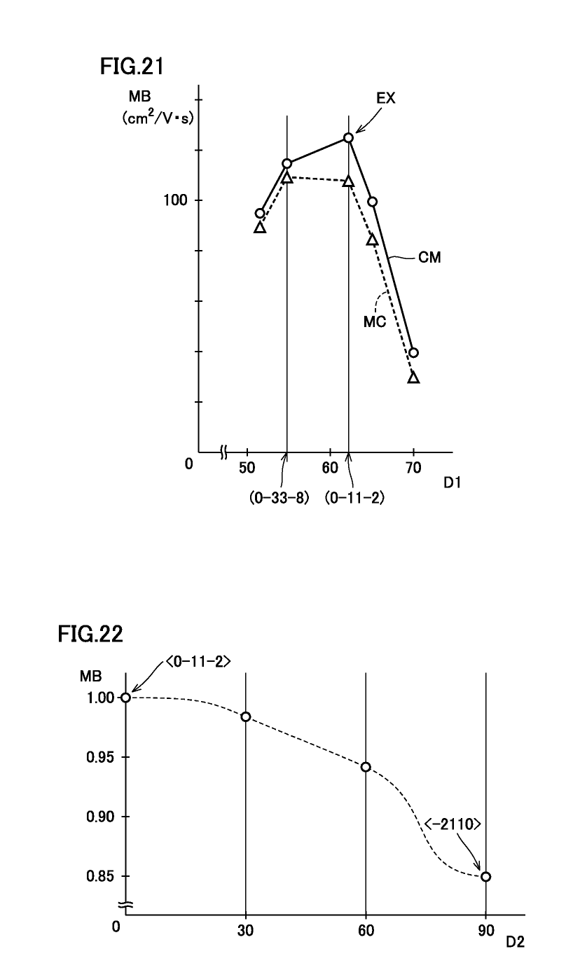

Relation between a crystal plane of sidewall surface SW and mobility MB of a channel surface will now be described with reference to FIG. 21. In the graph in FIG. 21, the abscissa represents an angle D1 formed between a macroscopic plane orientation of sidewall surface SW having a channel surface and the (000-1) plane and the ordinate represents mobility MB. A plot group CM corresponds to a case where sidewall surface SW is finished as a special surface through thermal etching and a plot group MC corresponds to a case where such thermal etching is not performed.

Mobility MB in plot group MC was highest when a macroscopic plane orientation of the surface of the channel surface was set to (0-33-8). This may be because, in a case where thermal etching is not performed, that is, a microscopic structure of the channel surface is not particularly controlled, by setting a macroscopic plane orientation to (0-33-8), a ratio of formation of a microscopic plane orientation (0-33-8), that is, a plane orientation (0-33-8) in a case of considering even an atomic level, was probabilistically high.

On the other hand, mobility MB in plot group CM was highest when a macroscopic plane orientation of the surface of the channel surface was set to (0-11-2) (an arrow FX). This may be because, as a large number of surfaces S1 each having the plane orientation (0-33-8) are regularly and densely arranged with surface S2 being interposed as shown in FIGS. 19 and 20, a ratio occupied by the microscopic plane orientation (0-33-8) was high at the surface of the channel surface.

It is noted that, on combined surface SR, mobility MB has orientation dependency. In the graph shown in FIG. 22, the abscissa represents an angle D2 between a channel direction and a <0-11-2> direction and the ordinate represents mobility MB (arbitrary unit) of the channel surface. A dashed line is supplementally provided in order to facilitate viewing of the graph. It was found from this graph that, in order to increase channel mobility MB, angle D2 which channel direction CD (FIG. 16) has is preferably not smaller than 0° and not greater than 60° and more preferably substantially 0°.

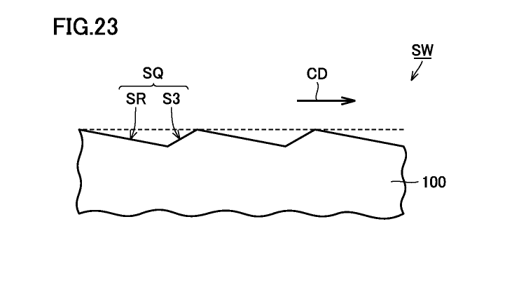

As shown in FIG. 23, sidewall surface SW may further include a surface S3 (a third surface) in addition to combined surface SR. More specifically, sidewall surface SW may include a combined surface SQ formed by periodic repetition of surface S3 and combined surface SR. In this case, an off angle of sidewall surface SW with respect to the {000-1} plane is deviated from 62° which is an ideal off angle of combined surface SR. This deviation is preferably small and preferably within a range of +10°. A surface included in such a range of angles is exemplified by a surface having a macroscopic plane orientation of a {0-33-8} plane. More preferably, an off angle of sidewall surface SW with respect to the (000-1) plane is deviated from 62° which is an ideal off angle of combined surface SR. This deviation is preferably small and preferably within a range of +10°. A surface included in such a range of angle is exemplified by a surface having a macroscopic plane orientation of a (0-33-8) plane.

Such a periodic structure can be observed, for example, with TEM or AFM.

for reasons described above, on sidewall surface SW (FIG. 1) of trench TR, p base layer 82 is preferably provided with a surface including surface S1 (FIG. 16) having a plane orientation {0-33-8}. Thus, of ON resistance of MOSFFT 200, a resistance of a channel portion which is a portion formed from p base layer 82 can be lowered. Therefore, a higher resistance of n drill layer 81 is allowed. Therefore, an impurity concentration in n drift layer 81 can be lower. Thus, a breakdown voltage can be higher.

This surface may microscopically include surface S1 and the surface may microscopically further include surface S2 (FIG. 16) having a plane orientation {0-11-1}. Surfaces S1 and S2 of this surface preferably form combined surface SR (FIG. 16) having a plane orientation {0-11-2}. This surface preferably macroscopically has an off angle of 62°⊥10° with respect to a {000-1} plane. Thus, a resistance in the channel portion can further be lowered.

It should be understood that the embodiment disclosed herein is illustrative and non-restrictive in every respect. The scope of the present invention is defined by the terms of the claims, rather than the description above, and is intended to include any modifications within the scope and meaning equivalent to the terms of the claims

### REFERENCE SIGNS LIST

40 mask layer; 80 single crystal substrate, 81 drift layer (first layer), 81a lower region (first region); 81b upper region (second region); 82 base layer (second layer); 83 n layer (third layer); 84 contact region, 85 embedded region; 85a connection portion (first portion); 85b extension portion (second portion); 91 gate oxide film (gate insulating film); 92 gate electrode; 93 interlayer insulating film; 94 source electrode (second electrode), 95 source interconnection layer, 98 drain electrode (first electrode), 100 epitaxial layer (silicon carbide layer), 200 MOSFET (silicon carbide semiconductor device); BT bottom surface; CD channel direction: P1 lower surface (first main surface); P2 upper surface (second main surface); S1 surface (first surface); S2 surface (second surface), SQ, SR combined surface; SW sidewall surface; TQ recess, and TR trench.

1. A silicon carbide semiconductor device, comprising:
a silicon carbide layer having a direction of thickness and having a first main surface and a second main surface opposed to said first main surface in said direction of thickness,
said silicon carbide layer including
a first layer forming said first main surface and having a first conductivity type,
a second layer provided on said first layer as being spaced apart from said first main surface by said first layer and having a second conductivity type, and
a third layer provided on said second layer as being spaced apart from said first layer by said second layer, forming said second main surface, and having said first conductivity type,
said silicon carbide layer being provided with a trench having a sidewall surface reaching said first layer from said second main surface through said third layer and said second layer,
said silicon carbide layer further including
a contact region which extends from said second main surface through said third layer and said second layer to a position deeper than an interface between said first and second layers, is distant from said first main surface, has said second conductivity type, and is higher in impurity concentration than said second layer, and
an embedded region which is distant from each of said first main surface, said second main surface, said second layer, said third layer, and said trench, is in contact with said contact region, and has said second conductivity type, said embedded region having a first portion lying between said contact region and said first main surface in said direction of thickness and a second portion extending from said first portion toward said trench;
a gate insulating film provided on said trench;
a gate electrode provided on said gate insulating film;
a first electrode provided on said first main surface of said silicon carbide layer; and
a second electrode provided on said second main surface of said silicon carbide layer and being in contact with each of said third layer and said contact region.

2. The silicon carbide semiconductor device according to claim 1, wherein
said first layer includes a first region which forms said first main surface and a second region which is provided between said first region and said second layer and is higher in impurity concentration than said first region, said sidewall surface of said trench reaches said first region through said second region, and said second region is located between said second portion of said embedded region and said second layer in said direction of thickness.

3. The silicon carbide semiconductor device according to claim 1, wherein
at least a part of said embedded region is higher in impurity concentration than said second layer.

4. The silicon carbide semiconductor device according to claim 1, wherein
said embedded region is distant from said trench by not smaller than 1 μm and not greater than 4 μm.

5. The silicon carbide semiconductor device according to claim 1, wherein
said second portion of said embedded region extends by not smaller than 1 μm from said first portion of said embedded region toward said trench.

6. The silicon carbide semiconductor device according to claim 1, wherein
on said sidewall surface of said trench, said second layer is provided with a surface including a first surface having a plane orientation {0-33-8}.

7. The silicon carbide semiconductor device according to claim 6, wherein
said surface microscopically includes said first surface and said surface microscopically further includes a second surface having a plane orientation {0-11-1}.

8. The silicon carbide semiconductor device according to claim 7, wherein
said first and second surfaces of said surface form a combined surface having a plane orientation {0-11-2}.

9. The silicon carbide semiconductor device according to claim 8, wherein said surface macroscopically has an off angle of 62°±10° with respect to a {000-1} plane.
